(19) United States
(12) Patent Application Publication
(10) Pub. No.: US 2015/0107359 A1
(43) Pub. Date: Apr. 23, 2015

(54) PIEZORESISTANCE SENSOR MODULE AND MEMS SENSOR HAVING THE SAME

(71) Applicant: SAMSUNG ELECTRO-MECHANICS CO., LTD., Suwon-Si (KR)

(72) Inventors: Jeong Suong YANG, Suwon-Si (KR); Je Hong Kyoung, Suwon-Si (KR); Ho Phil Jung, Suwon-Si (KR); Hyung Jae Park, Suwon-Si (KR); Dong Hyun Park, Suwon-Si (KR)

(73) Assignee: SAMSUNG ELECTRO-MECHANICS CO., LTD., Suwon-Si (KR)

(21) Appl. No.: 14/499,182

(22) Filed: Sep. 28, 2014

(30) Foreign Application Priority Data
Oct. 22, 2013 (KR) 10-2013-0126092

(51) Int. Cl. G01P 15/12; B81B 7/02; B81B 7/00

(52) U.S. Cl. CPC G01P 15/123; B81B 7/00; B81B 7/02
USPC 73/514.33

(57) ABSTRACT

Disclosed herein is a piezoresistance sensor module including: a piezoresistor, a depletion layer formed in a region of a portion of the piezoresistor, an insulator formed to cover the depletion layer and one surface of the piezoresistor, and a piezoelectric capacitor formed on the insulator so as to be opposite to the depletion layer.

### CROSS REFERENCE TO RELATED APPLICATION

This application claims the benefit of Korean Patent Application No. 10-2013-0126092, filed on Oct. 22, 2013, entitled “Piezoresistance Sensor Module and MEMS Sensor Having the Same”, which is hereby incorporated by reference in its entirety into this application.

### BACKGROUND OF THE INVENTION

1. Technical Field

The present invention relates to a piezoresistance sensor module and a MEMS sensor having the same.

2. Description of the Related Art

Generally, an inertial sensor has been used in a car, aircraft, mobile communication terminals, toys, and the like and requires a 3-axis acceleration and angular velocity sensor which measures X-axis, Y-axis and Z-axis accelerations and angular velocities and has been developed to have high performance and be miniaturized to detect a fine acceleration.

Further, the acceleration sensor according to the prior art includes technical features which converts motions of a mass body and a flexible part into electrical signals and as a type of the acceleration sensor, there are a piezoresistive type which detects the motion of the mass body from a change in resistance of a piezoresistance element disposed in the flexible part, a capacitive type which detects the motion of the mass body from a change in capacitance with a fixed electrode, and the like.

Further, the piezoresistive type uses an element which has a variable resistance value due to a stress, and for example, the resistance value is increased at a place at which a tensile stress is distributed and the resistance value is reduced at a place at which a compression stress is distributed.

Further, as an example of the inertial sensor, the acceleration sensor of the piezoresistive type according to the prior art including the Prior Art Document may not maintain a stabilization state due to an external impact, and the like, when rigidity of the sensor, such as a thickness of a beam, is reduced to improve sensitivity.

### PRIOR ART DOCUMENT

### Patent Document

(Patent Document 1) US 20060156818 A

### SUMMARY OF THE INVENTION

The present invention has been made in an effort to provide a piezoresistance sensor module capable of increasing sensitivity while maintaining rigidity of a beam, by forming a depletion layer in a piezoresistor and controlling the depletion layer using a piezoelectric capacitor, and an MEMS sensor having the same.

According to a preferred embodiment of the present invention, there is provided a piezoresistance sensor module, including: a piezoresistor; a depletion layer formed in a region of a portion of the piezoresistor; an insulator formed to cover the depletion layer and one surface of the piezoresistor; and a piezoelectric capacitor formed on the insulator so as to be opposite to the depletion layer.

One surface of the insulator may be coupled with a piezoresistor in which the depletion layer is formed and the other surface of the insulator may be coupled with the piezoelectric capacitor.

The piezoelectric capacitor may be configured of an electrode unit and the electrode unit may include a lower electrode coupled with the insulator and a piezoelectric material formed on one surface of the lower electrode.

The electrode unit may be further provided with an upper electrode formed in the piezoelectric material, one surface of the piezoelectric material may be coupled with the lower electrode, and the other surface of the piezoelectric material may be coupled with the upper electrode.

The piezoresistance sensor module may further include: a connection electrode coupled with the piezoresistor to detect a signal of the piezoresistor.

The insulator may be provided with a through hole so that the connection electrode is exposed to an outside of the piezoresistance sensor module, and the connection electrode may be connected to the piezoresistor covered with the insulator through the through hole.

According to another preferred embodiment of the present invention, there is provided an MEMS sensor including: a mass body, a flexible substrate displaceably coupled with the mass body and provided with a piezoresistance sensor module, and a support part supporting the flexible substrate so that the mass body floats, wherein the piezoresistance sensor module includes a piezoresistor, a depletion layer formed in a region of a portion of the piezoresistor, an insulator formed to cover the depletion layer and one surface of the piezoresistor, and a piezoelectric capacitor formed on the insulator so as to be opposite to the depletion layer.

One surface of the insulator may be coupled with a piezoresistor in which the depletion layer is formed and the other surface of the insulator may be coupled with the piezoelectric capacitor.

The piezoelectric capacitor may be configured of an electrode unit and the electrode unit may include a lower electrode coupled with the insulator and a piezoelectric material formed on one surface of the lower electrode.

The electrode unit may further include an upper electrode formed in the piezoelectric material, one surface of the piezoelectric material may be coupled with the lower electrode, and the other surface of the piezoelectric material may be coupled with the upper electrode.

The MEMS sensor may further include: a connection electrode coupled with the piezoresistor to detect a signal of the piezoresistor.

The insulator may be provided with a through hole so that the connection electrode is exposed to an outside of the piezoresistance sensor module, and the connection electrode may be connected to the piezoresistor covered with the insulator through the through hole.

The MEMS sensor may further include: an upper cover coupled with a flexible substrate of the sensor unit to cover the flexible substrate on which the piezoresitance sensor module is formed; and a lower cover coupled with the support part to cover the mass body.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a configuration diagram schematically illustrating a piezeoresistance sensor module according to a preferred embodiment of the present invention; and

FIG. 2 is a cross-sectional view schematically illustrating an MEMS sensor having a piezoresistance sensor module according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

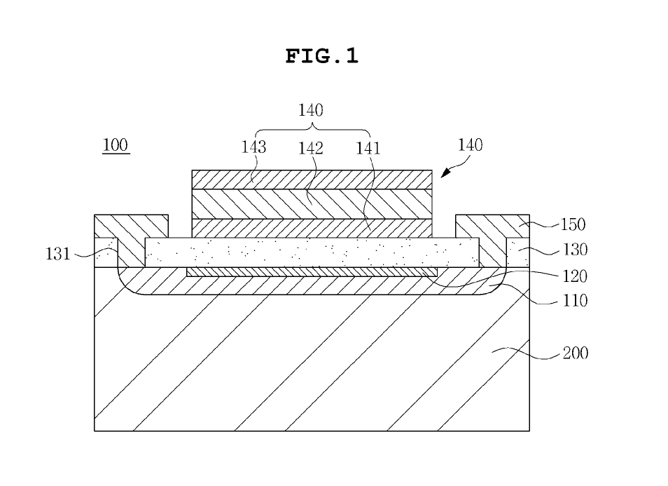

FIG. 1 is a configuration diagram schematically illustrating a piezeoresistance sensor module according to a preferred embodiment of the present invention; and As illustrated in FIG. 1, a piezoresistance sensor module 100 includes a piezoresistor 110, a depletion layer 120, an insulator 130, and an electrode unit 140, and the piezoresistance module 100 is disposed on a flexible substrate 200.

In more detail, the piezoresistor 110 is to detect a displacement depending on a change in a resistance value, and when a displacement occurs in the flexible substrate 200 on which the piezoresistance sensor module 100 is mounted, detects a generated stress, that is, a compression stress or a tensile stress as a change in a resistance value.

Further, the depletion layer 120 is to improve sensitivity by controlling an area of the piezoresistor 110 and may be controlled by a piezoelectric capacitor which is formed to be opposite to the depletion layer 120. That is, when a thickness of the depletion layer is increased, a formation area of the piezoresistor becomes small and sensing sensitivity is improved.

Therefore, when the thickness of the flexible substrate is formed to be thinner to improve the sensitivity according to the prior art, a problem vulnerable to an external impact may be solved and the sensing sensitivity may be improved while maintaining the thickness of the reliable flexible substrate.

Further, the insulating body 130 is formed to cover the depletion layer 120 and the electrode unit 140 which is the piezoelectric capacitor is formed on the insulator 130 to be opposite to the depletion layer 120.

That is, one surface of the insulator 130 is coupled with the piezoresistor 110 in which the depletion layer 120 is formed and the other surface of the other insulator 130 is coupled with the piezoelectric capacitor.

Further, the electrode unit 140 includes a lower electrode 141 and a piezoelectric material 142, and an upper electrode 143 may be further disposed on an upper portion of the piezoelectric material 142.

Further, the piezoresistance sensor module 100 is configured to further include a connection electrode 150 which is electrically connected to the piezoresistor 110 so as to detect a signal of the piezoresistor 110. Further, the connection electrode 150 is connected to the piezoresistor 110 and penetrates through the insulator 130 to be exposed to an outside of the piezoresistance sensor module 100. To this end, the insulator 130 is provided with a through hole 131 and the connection electrode 150 may be connected to the piezoresistor 110 covered with the insulator 130, through the through hole 131.

By the above configuration, in the piezoresistance sensor module 100 according to the preferred embodiment of the present invention, the depletion layer 120 formed in the piezoresistor 110 is controlled by the electrode unit 140 and the area of the piezoresistor 110 is changed by the depletion layer 120, thereby increasing the sensitivity.

Further, a thickness of the insulator and a polarized amount of the piezoelectric material are controlled so that only the depletion layer 120 is generated and an inversion layer is not generated.

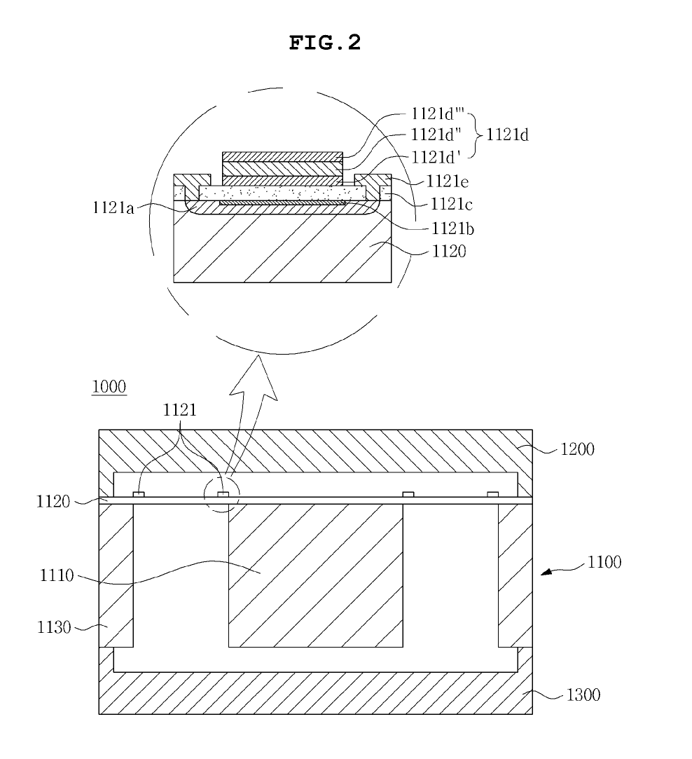

FIG. 2 is a cross-sectional view schematically illustrating an MEMS sensor having a piezoresistance sensor module according to a preferred embodiment of the present invention. As illustrated in FIG. 2, according to the preferred embodiment of the present invention, an MEMS sensor 1000 is implemented as an acceleration sensor and is configured to include a sensor unit 1100. Further, the sensor unit 1100 includes a mass body 1110, a flexible substrate 1120, and a support part 1130.

In more detail, the mass body 1110 is displaced by an external force and is displaceably coupled with the flexible substrate 1120.

Further, the support part 1130 is coupled with the flexible substrate 1120 and supports the mass body 1110 so that the mass body 1110 floats.

Further, the flexible substrate 1120 is provided with a piezoresistance sensor module 1121 and the piezoresistance sensor module 1121 may be formed to be adjacent to the mass body 1110 and the support part 1130. This considers the state in which a stress is concentrated on an adjacent region of the mass body 1110 and the support part 1130 which are coupled with the flexible substrate 1120.

In addition, the MEMS sensor 1000 may further include an upper cover 1200 and a lower cover 1300. Further, the upper cover 1200 is coupled with the sensor unit to cover one side of the sensor unit 110 and the lower cover 1300 is coupled with the sensor unit 1100 to cover the other side of the sensor unit 110.

That is, the upper cover 1200 is coupled with the flexible substrate 1120 of the sensor unit to cover the flexible substrate 1120 on which the piezoresistance sensing module 1121 of the sensor unit is formed and the lower substrate 1300 is coupled with the support part 1130 of the sensor unit 1100 to cover the mass body. Further, the upper cover 1200 and the lower cover 1300 may be applied with a polymer, such as a bonding agent, to be coupled with the sensor unit 1100.

Further, as illustrated in more detail in an enlarged view, the piezoresistance sensor module 1121 includes a piezoresistor 1121a, a depletion layer 1121b, an insulator 1121c, and an electrode unit 1121d, and the piezoresistance sensor module 1121 is disposed on a flexible substrate 1200.

In more detail, the piezoresistor 1121a is to detect a displacement of the mass body 1110 depending on a change in a resistance value, and when the displacement occurs in the mass body 1100, detects the generated stress, that is, the compression stress or the tensile stress as the change in a resistance value.

Further, the depletion layer 1121b is to improve sensitivity by controlling an area of the piezoresistor 1121a and may be controlled by the electrode unit 1121d which is a piezoelectric capacitor formed to be opposite to the depletion layer.

To this end, an upper surface of the depletion layer 1121b is provided with the insulator 1121c and an upper portion of the insulator 1121c is provided with the electrode unit 1121d.

Further, the electrode unit 1121d includes a lower electrode 1121d′ and a piezoelectric material 1121d″, and an upper electrode 1121d′ may be further disposed on an upper portion of the piezoelectric material 1121d″.

Further, the piezoresistance sensor module 1121 is configured to further include a connection electrode 1121e which is electrically connected to the piezoresistor 1121a so as to detect a signal of the piezoresistor 1121a.

By the above configuration, according to the preferred embodiment of the present invention, as the area of the piezoresistor 1121a is changed by the depletion layer 1121b of the piezoresistance sensor module 1121 to improve the sensing sensitivity, the high reliable MEMS sensor 1000 may be obtained.

According to the preferred embodiments of the present invention, it is possible to obtain the piezoresistance sensor module which may increase the sensitivity while maintaining the rigidity of the beam, by forming the depletion layer in the piezoresistor and controlling the depletion layer using the piezoelectric capacitor, and the MEMS sensor having the same.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A piezoresistance sensor module, comprising:
a piezoresistor;
a depletion layer formed in a region of a portion of the piezoresistor;
an insulator formed to cover the depletion layer and one surface of the piezoresistor; and
a piezoelectric capacitor formed on the insulator so as to be opposite to the depletion layer.

2. The piezoresistance sensor module as set forth in claim 1, wherein one surface of the insulator is coupled with a piezoresistor in which the depletion layer is formed and the other surface of the insulator is coupled with the piezoelectric capacitor.

3. The piezoresistance sensor module as set forth in claim 1, wherein the piezoelectric capacitor is configured of an electrode unit, and
the electrode unit includes a lower electrode coupled with the insulator and a piezoelectric material formed on one surface of the lower electrode.

4. The piezoresistance sensor module as set forth in claim 3, wherein the electrode unit is further provided with an upper electrode formed in the piezoelectric material, one surface of the piezoelectric material is coupled with the lower electrode, and the other surface of the piezoelectric material is coupled with the upper electrode.

5. The piezoresistance sensor module as set forth in claim 1, further comprising:
a connection electrode coupled with the piezoresistor to detect a signal of the piezoresistor.

6. The piezoresistance sensor module as set forth in claim 5, wherein the insulator is provided with a through hole so that the connection electrode is exposed to an outside of the piezoresistance sensor module, and the connection electrode is connected to the piezoresistor covered with the insulator through the through hole.

7. An MEMS sensor, comprising:
a mass body, a flexible substrate displaceably coupled with the mass body and provided with a piezoresistance sensor module, and a support part supporting the flexible substrate so that the mass body floats,
wherein the piezoresistance sensor module includes a piezoresistor, a depletion layer formed in a region of a portion of the piezoresistor, an insulator formed to cover the depletion layer and one surface of the piezoresistor, and a piezoelectric capacitor formed on the insulator so as to be opposite to the depletion layer.

8. The MEMS sensor as set forth in claim 7, wherein one surface of the insulator is coupled with a piezoresistor in which the depletion layer is formed and the other surface of the insulator is coupled with the piezoelectric capacitor.

9. The MEMS sensor as set forth in claim 7, wherein the piezoelectric capacitor is configured of an electrode unit, and
the electrode unit includes a lower electrode coupled with the insulator and a piezoelectric material formed on one surface of the lower electrode.

10. The MEMS sensor as set forth in claim 9, wherein the electrode unit further includes an upper electrode formed in the piezoelectric material, one surface of the piezoelectric material is coupled with the lower electrode, and the other surface of the piezoelectric material is coupled with the upper electrode.

11. The MEMS sensor as set forth in claim 7, further comprising:
a connection electrode coupled with the piezoresistor to detect a signal of the piezoresistor.

12. The MEMS sensor as set forth in claim 11, wherein the insulator is provided with a through hole so that the connection electrode is exposed to an outside of the piezoresistance sensor module, and the connection electrode is connected to the piezoresistor covered with the insulator through the through hole.

13. The MEMS sensor as set forth in claim 7, further comprising:
an upper cover coupled with a flexible substrate of the sensor unit to cover the flexible substrate on which the piezoresistance sensor module is formed; and
a lower cover coupled with the support part to cover the mass body.
